(19) United States
(12) Patent Application Publication
(10) Pub. No.: US 2005/0275106 A1
(43) Pub. Date: Dec. 15, 2005

(54) Electronic isolation device

(76) Inventors: Peter J. Fricke, Corvallis, OR (US); Andrew L. Van Brocklin, Corvallis, OR (US); Warren B. Jackson, San Francisco, CA (US); Barbara Crivelli, Milano (IT); Riccardo Sotgiu, Varese (IT)

Correspondence Address: HEWLETT-PACKARD COMPANY;Intellectual Property Administration, P.O. Box 272400, Fort Collins, CO, 80527-2400, US

(21) Appl. No.: 10/867,307

(22) Filed: Jun. 14, 2004

(51) Int. Cl. H01L 23/48; H01L 23/58

(52) U.S. Cl. 257/758; 257/635; 257/646; 257/760

(57) ABSTRACT

A two-terminal electronic isolation device has an anode, a cathode, an integral tunnel junction, and a current-injection layer. The current-injection layer comprises a silicon-rich oxide.

### CROSS-REFERENCE TO RELATED APPLICATION

This application is related to co-pending and commonly assigned application Ser. No. 10/772,945, filed Feb. 4, 2004 (attorney docket no. 200310842-1), the entire disclosure of which is incorporated herein by reference.

### TECHNICAL FIELD

This invention relates generally to electronic isolation devices and methods for fabricating such devices.

### BACKGROUND

Markets for computers, video games, televisions, portable telephones, PDAs and other electrical devices are requiring increasingly larger amounts of memory to store images, photographs, videos, movies, music, and other storage intensive data. At the same time, as computer and other electrical equipment prices continue to drop, the manufacturers of storage devices, such as memory devices and hard drives, need to lower the cost of their components. Thus, besides increasing the storage density of their device, manufacturers of storage devices must also reduce costs. This trend of increasing memory storage density while reducing the costs required to create the storage has been on-going for many years. There is accordingly a need for economical, high capacity memory structures, methods for control of such memory structures, and economical methods for fabricating such structures, especially methods that are compatible with methods used to fabricate other elements of integrated circuits. While resistive elements, transistors, and diodes have been used as control elements in the past, they have had various shortcomings in speed, silicon area requirements, and in allowing “sneak paths.” Conventional methods for permanently isolating devices in a memory or other integrated circuit include, for example, a shallow oxide-filled isolation trench.

More generally, there is a continuing and growing need to isolate devices of an integrated circuit from other devices. For example, in integrated circuit testing, it is often necessary to isolate a particular integrated circuit or portion of an integrated circuit from a common power supply or from a common signal line. Permanent isolation devices, such as fuses, are sometimes usable for such purposes. A fuse is interposed between the portions to be isolated, ensuring permanent isolation when the fuse is blown. Antifuses operate in a reverse manner.

However, there are many situations that require only temporary isolation. A temporary isolation device (e.g., a diode, transistor or other element controlled by an electrical signal) may be interposed between the portions of an integrated circuit to be isolated from each other. The characteristics required for such isolation devices include small size, reliable operation, and low leakage current. Additionally, there is a need for lower-cost processes for fabricating isolation devices.

### BRIEF DESCRIPTION OF THE DRAWINGS

The features and advantages of the disclosure will readily be appreciated by persons skilled in the art from the following detailed description when read in conjunction with the drawings, wherein:

FIG. 1 is a side elevation cross-sectional view of an embodiment of an electronic isolation device in accordance with the invention.

FIG. 2 is a schematic diagram of an equivalent circuit of an embodiment of an electronic isolation device.

FIG. 3 is an energy-band diagram.

FIG. 4 is a flowchart illustrating an embodiment of a process for fabricating an electronic isolation device.

### DETAILED DESCRIPTION OF EMBODIMENTS

For clarity of the description, the drawings are not drawn to a uniform scale. In particular, vertical and horizontal scales may differ from each other and may vary within a drawing and from one drawing to another. In this regard, directional terminology, such as “top,” “bottom,” “front,” “back,” “leading,” “trailing,” etc., is used with reference to the orientation of the drawing figure(s) being described. Because components of the invention can be positioned in a number of different orientations, the directional terminology is used for purposes of illustration and is in no way limiting.

One aspect of the invention provides a two-terminal electronic isolation device that has an anode, a cathode, an integral tunnel junction, and a current-injection layer. The current-injection layer comprises a silicon-rich oxide.

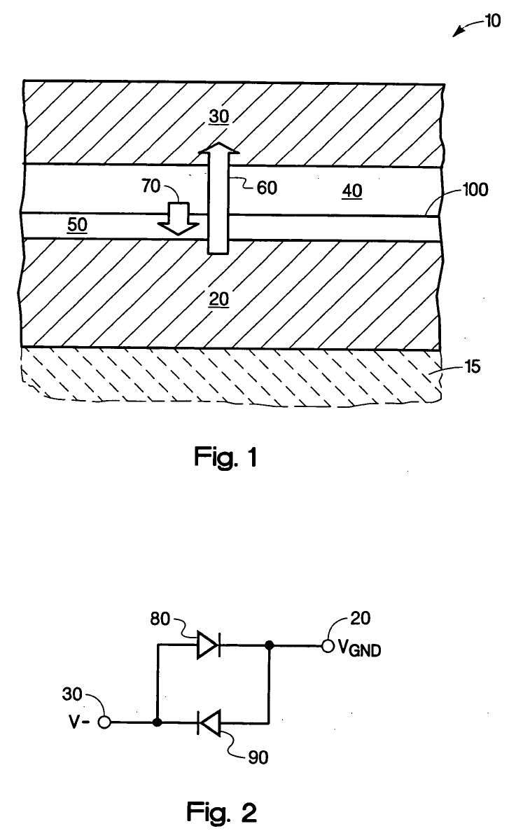

FIG. 1 shows a side elevation cross-sectional view of an embodiment of a two-terminal electronic isolation device 10 including an anode 20, a cathode 30, a tunnel junction 50 including a thin layer of insulator, and a current-injection layer 40, which is comprised of a silicon-rich oxide. The thin layer of insulator of the tunnel junction 50 may be a thin layer of aluminum oxide (Al₂O₃), silicon dioxide (SiO₂), silicon oxynitride, or other high-dielectric-constant (high-K) material, for example. Both the conductive cathode and anode may comprise any of a number of conductive materials, such as titanium or titanium nitride (TiN). Other conductive materials suitable for the cathode and anode include aluminum, tungsten, gold, platinum, and other metals, and semiconductors such as silicon (e.g., crystalline, polycrystalline, microcrystalline, amorphous, or doped semiconductors). As shown in FIG. 1, the tunnel junction's thin layer of insulator 50 may be disposed adjacent to the anode electrode 20, the silicon-rich oxide layer 40 may be disposed adjacent to the tunnel junction layer 50, and the cathode electrode 30 may be disposed adjacent to the silicon-rich oxide layer 40. Layer thicknesses in FIG. 1 are not drawn to any uniform scale. The thin layer of insulator of the tunnel junction 50 may have a thickness of less than about ten nanometers, and the silicon-rich-oxide current-injection layer 40 may have a thickness of less than about 100 nanometers, for example. The thickness of the conductive anode and cathode layers 20 and 30 is not critical. Those conductive layers may have thicknesses of about 20 to 500 nanometers, for example, typically about 100 nanometers, to provide reasonably low electrical resistance.

FIG. 1 also shows with arrows the directions of the device current 60 and the current 70 of electrons injected across interface 100 from silicon-rich oxide layer 40 and into the tunnel junction's thin layer of insulator 50.

The silicon-rich oxide layer has a composition of SiOₓ, where x is less than two, or has a composition characterized by an elemental molar ratio of silicon to oxygen between about 0.51 and about one. The excess quantity of silicon (over the amount for stoichiometric silicon dioxide) can be as low as about one percent. Typically, the excess silicon may be between about 10% and about 50%. The excess silicon in such compositions typically exists aggregated in islands or clusters of silicon atoms within a silicon dioxide matrix.

The two-terminal electronic isolation device may be characterized by a forward-bias resistance and a reverse-bias resistance. FIG. 2 is a schematic diagram of an equivalent circuit of device 10. The two diodes 80 and 90 connected in parallel (but having opposite polarities relative to each other) represent the non-linear tunnel-junction resistance between anode 20 and cathode 30. For example, with forward bias, the resistance with 50 millivolts applied may be about ten megohms, and with one volt applied may be about one megohm. With reverse bias of 50 millivolts applied, the resistance may be about one gigohm.

The electrical characteristics of device 10 are controlled by thickness of the insulating layers, by doping concentrations, and by fabrication conditions, as described hereinbelow. With a device constructed in accordance with the present invention, the ratio of the reverse-bias resistance to the forward-bias resistance exceeds about 1,000 or may even exceed about 10,000. Thus, isolation device 10 exhibits characteristics that enable electrical selection and isolation in integrated circuit electronics applications. The resistance ratio of 3 to 4 orders of magnitude from forward bias to reverse bias allows device 10 to enable or select electronic circuits when in a forward bias configuration and to disable, deselect, or isolate electronic circuits when in the reverse bias configuration. Isolation device 10 or a number of such devices may be incorporated in an integrated circuit to perform these functions.

Silicon-rich oxide (SRO) layer 40 enhances tunneling by a factor, M, that can be about 1.75. This allows higher layer yields in manufacturing due to the thicker oxide that can be used.

Although silicon dioxide has a high mobility for electrons (about 30 cm²/Vsec), it forms large interfacial energy bands (>2 eV) with contacting metals or semiconductors because of its large energy bandgap of about 9 eV which makes current injection into it very difficult. This results in the excellent insulating properties of capacitors using SiO₂ as their dielectric.

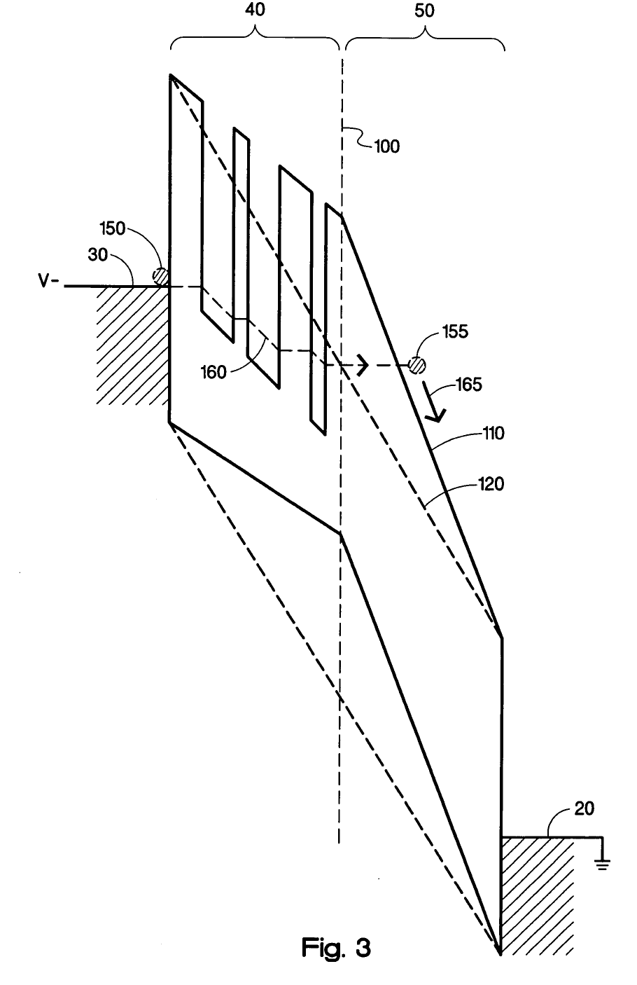

FIG. 3 is adapted from FIG. 17 in the paper by D. J. DiMaria et al., J. Appl. Phys. V. 51(15), May 1980, pp. 2722-2735, from FIG. 2 in the paper by D. J. DiMaria et al., J. Appl. Phys. V. 55(8), Apr. 15, 1984, pp. 3000-3019, and from FIG. 8 in the chapter by D. J. DiMaria in “High Current Injection Into SiO₂ Using Si-rich SiO₂ Films and Experimental Applications,” The Physics of MOS Insulators,” (G. Lucovsky et al., Eds.), Pergamon Press, New York, 1980, pp. 1-18. The entire disclosure of each of these three publications by D. J. DiMaria et al. is incorporated herein by reference.

FIG. 3 shows an energy-band diagram illustrating operation of device 10. For comparison, dashed lines 120 show the field that would exist across a homogeneous insulator layer between anode 30 and cathode 20. The energy band 110 (solid-line) shows the reduced electric field and the silicon inclusions within the silicon-rich oxide region, and solid line 110 also shows the increased electric field potential within insulator layer 50. The path of an electron 150 moving through SRO region 40 is shown by dashed line 160. The electron tunnels from interface 100 through insulator layer 50. Such an electron 155 is accelerated (arrow 165) toward anode 20 in the relatively higher electric field at the right side of FIG. 3. Thus, an apparent reduction of the interfacial energy barrier is considered to be partly obtained by the localized silicon clusters islands within the silicon-rich oxide layer 40 serving as intermediate hopping sites to tunnel through the interfacial energy barrier.

The apparent barrier is also reduced by field enhancement due to sharp injection points on the silicon inclusions within the silicon dioxide of the SRO. The sharp points concentrate the field into a small region thereby lowering the threshold voltage necessary to initiate injection into the oxide, but these sharp points also reduce the total area of the device participating in the current injection. The cumulative effect of the island-enhanced tunneling, the field enhancement at sharp points, and the reduction of area can be summarized by an enhancement factor. The injection phenomenon has been shown to be limited by the interface 100 of the silicon-rich oxide layer with the insulator layer 50. The current injection and enhanced tunneling are unidirectional. The currents exhibit Fowler-Nordheim-like behavior, Schottky emission current voltage characteristics, and weak temperature dependence. Low-voltage breakdowns of insulator layers, which are considered to be associated with the field at the cathode, are suppressed when a thin silicon-rich oxide layer 40 is present. Reversible space charge build-up in this thin silicon-rich oxide layer tends to relax high electric fields at the conductive electrode contacts. This is believed to result in the observed dramatic increase in breakdown voltage.

The tunnel oxide characteristics are primarily dictated by thickness of the oxide. The enhancement factor from using SRO with current injection allows a thicker oxide to have current/voltage characteristics that are similar to a thinner oxide without current injection.

At least some of the embodiments described herein are believed to operate in accordance with the aforementioned field enhancement and tunneling enhancement factor. However, the invention should not be construed as being limited to the consequences of any particular theory of operation.

Thus, an aspect of the invention is an integrated circuit including a two-terminal electronic isolation device comprising an anode electrode 20, a tunnel junction (comprising a thin layer of insulator 50) disposed adjacent to the anode electrode 20, a silicon-rich oxide layer 40 disposed adjacent to the tunnel junction layer 50, and a cathode electrode 30 disposed adjacent to the silicon-rich oxide layer. All the layers 20, 30, 40, and 50 may be thin films but are not necessarily all of the same thickness. For example, the tunnel junction film 50 may be about an order of magnitude thinner than the silicon-rich-oxide current-injection film 40.

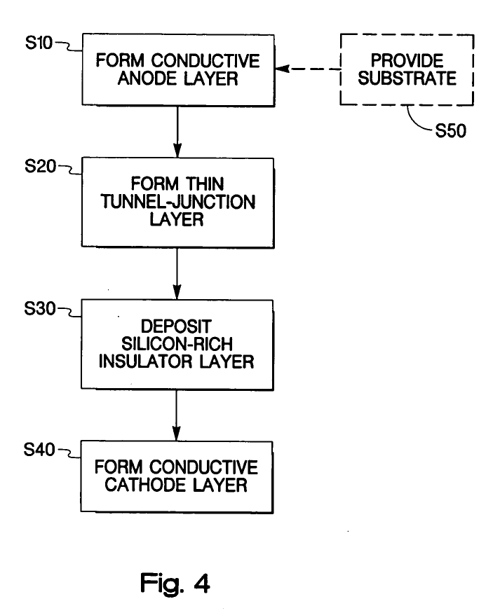

Another aspect of the invention is a method of fabricating a two-terminal electronic isolation device. An embodiment of such a method is shown in the flowchart, FIG. 4. Method steps are indicated by reference numerals S10, . . . ,S50. This method embodiment includes the steps of forming a conductive anode layer (S10), forming a thin tunnel-junction layer (S20), depositing a thin silicon-rich oxide layer (S30), and forming a conductive cathode layer (S40). The silicon-rich oxide layer has a composition of SiOₓ, where x is less than two. Either the anode or the cathode may provide a substrate for the other films, depending on the order in which the layers are formed. If the device is to be made on a separate substrate, the method also includes a step (S50) of providing the separate substrate, e.g., a silicon wafer with an insulating top surface. The conductive films for cathode 30 and anode 20 may be formed by depositing any of a number of conductive materials, such as titanium, titanium nitride (TiN), or other conductive materials. The conductive anode and/or cathode layers may also be patterned, e.g., by known lithographic techniques. If the conductive anode layer is to be patterned, the method includes a step of patterning the conductive anode layer. Similarly, if the conductive cathode layer is to be patterned, the method includes a step of patterning the conductive cathode layer.

The electrical characteristics of device 10 are controlled by the thickness of the insulating layers 40 and 50, by doping concentrations, and by fabrication conditions such as chemical vapor composition and pressures, and deposition temperatures.

The step of depositing a thin silicon-rich oxide layer 40 may be performed by rapid thermal chemical vapor deposition (RTCVD) or by plasma-enhanced chemical vapor deposition (PECVD). In a PECVD process, for example, the plasma may be formed in a mixture of N₂O and silane (SiH₄) gases at 650° C. and standard pressure. The deposition may be performed at 600° C., but at a higher pressure to achieve a reasonable deposition rate. The ratio of SiH₄ gas to N₂O gas is regulated to control the silicon content while depositing an oxide SiOₓ where x is less than two. The deposited silicon-rich oxide layer 40 has a composition which, alternatively, may be characterized by an elemental molar ratio of silicon to oxygen between about 0.51 and about one. In other words, the process is controlled to provide an oxide having “excess” silicon, i.e., silicon in excess of the amount required for stoichiometric silicon dioxide. For example, the ratio of SiH₄:N₂O may be about 1:20 for about 1% excess silicon in the SRO. Typically, SiH₄:N₂O ratios used are between about 1:10 for about 10% excess silicon and about 1:5 for about 50% excess silicon. The step of depositing a thin tunnel-junction insulator layer 50 may also be performed by rapid thermal chemical vapor deposition (RTCVD), by plasma-enhanced chemical vapor deposition (PECVD), or by atomic layer deposition (ALD) of Al₂O₃ or stoichiometric SiO₂.

Thus, a more specific embodiment of a method for fabricating a two-terminal electronic isolation device includes the steps of providing a substrate comprising an insulating layer over a planar silicon wafer, forming a conductive anode layer on the substrate, forming a thin tunnel-junction layer, depositing a thin silicon-rich oxide layer contiguous with the tunnel-junction layer, and forming a conductive cathode layer contiguous with the silicon-rich oxide layer. Again, the silicon-rich oxide (SRO) layer has a composition of SiOₓ, where x is less than two, or has a composition characterized by an elemental molar ratio of silicon to oxygen between about 0.51 and about one.

The resulting electronic isolation-device structure is a two-terminal active electronic device characterized by its ability to pass an electric current more easily from anode to cathode than from cathode to anode, i.e., a diode that utilizes a current-injection layer of silicon-rich oxide (SRO). The device has improved resistance ratio between forward- and reverse-bias diode characteristics compared to a conventional tunnel junction. It can be used in many applications in place of a conventional amorphous or microcrystalline semiconducting diode structure, but with improved dynamic characteristics due to absence of traps compared with an amorphous or microcrystalline semiconducting diode.

### INDUSTRIAL APPLICABILITY

Devices made in accordance with the invention are useful in memories and other integrated circuit applications. Two-terminal electronic isolation devices made in accordance with the invention can be used to enable or select electronic circuits in a forward bias configuration and to disable, deselect, or isolate electronic circuits in a reverse bias configuration.

Although the foregoing has been a description and illustration of specific embodiments of the invention, various modifications and changes thereto can be made by persons skilled in the art without departing from the scope and spirit of the invention as defined by the following claims. For example, the order of method steps may be varied to some extent. Specifically, if a separate substrate is used, either the anode or cathode may be deposited on the substrate, and the order of steps is reversed between those two cases. Current injecting materials other than SRO may be employed.

1. A two-terminal electronic isolation device comprising:
a cathode, an anode, a tunnel junction including a thin layer of insulator, and a current-injection layer, wherein the current-injection layer comprises a silicon-rich oxide.

2. The two-terminal electronic isolation device of claim 1, wherein the thin layer of insulator comprises silicon dioxide.

3. The two-terminal electronic isolation device of claim 1, wherein the thin layer of insulator comprises aluminum oxide.

4. The two-terminal electronic isolation device of claim 1 wherein the thin layer of insulator of the tunnel junction has a thickness of less than about ten nanometers.

5. The two-terminal electronic isolation device of claim 1, wherein the silicon-rich oxide layer has a thickness of less than about 100 nanometers.

6. The two-terminal electronic isolation device of claim 1, wherein the silicon-rich oxide layer has a composition of SiOₓ, wherein x is less than 2.

7. The two-terminal electronic isolation device of claim 1, wherein the silicon-rich oxide layer has a composition characterized by an elemental molar ratio of silicon to oxygen between about 0.51 and about one.

8. The two-terminal electronic isolation device of claim 1, wherein the silicon-rich oxide layer comprises clusters of silicon atoms within a silicon dioxide matrix.

9. The two-terminal electronic isolation device of claim 1, wherein the silicon-rich oxide layer comprises silicon clusters within a silicon dioxide matrix.

10. The two-terminal electronic isolation device of claim 1, wherein the cathode comprises titanium.

11. The two-terminal electronic isolation device of claim 1, wherein the cathode comprises titanium nitride.

12. The two-terminal electronic isolation device of claim 1, wherein the anode comprises titanium.

13. The two-terminal electronic isolation device of claim 1, wherein the anode comprises titanium nitride.

14. The two-terminal electronic isolation device of claim 1, wherein the isolation device has a forward-bias resistance and a reverse-bias resistance, and the ratio of the reverse-bias resistance to the forward-bias resistance exceeds about 1,000.

15. The two-terminal electronic isolation device of claim 14, wherein the ratio of the reverse-bias resistance to the forward-bias resistance exceeds about 10,000.

16. An integrated circuit comprising the two-terminal electronic isolation device of claim 1.

17. A two-terminal electronic isolation device comprising:
an anode electrode,
a tunnel junction disposed contiguous with the anode electrode, the tunnel junction comprising a thin layer of insulator,
a silicon-rich oxide layer disposed contiguous with the tunnel junction, and
a cathode electrode disposed contiguous with the silicon-rich oxide layer.

18. The two-terminal electronic isolation device of claim 17, wherein the isolation device has a forward-bias resistance and a reverse-bias resistance, and the ratio of the reverse-bias resistance to the forward-bias resistance exceeds about 1,000.

19. The two-terminal electronic isolation device of claim 18, wherein the ratio of the reverse-bias resistance to the forward-bias resistance exceeds about 10,000.

20. An integrated circuit comprising the two-terminal electronic isolation device of claim 17.

21. A method for fabricating a two-terminal electronic isolation device, the method comprising the steps of:
a) forming a conductive anode layer,
b) forming a thin tunnel-junction layer,
c) depositing a thin silicon-rich oxide layer having a composition of SiOx, wherein x is less than two, and
d) forming a conductive cathode layer.

22. The method of claim 21, wherein the steps are performed in the order recited.

23. The method of claim 21, wherein the step c) of depositing a thin silicon-rich oxide layer is performed by rapid thermal chemical vapor deposition (RTCVD).

24. The method of claim 21, wherein the step c) of depositing a thin silicon-rich oxide layer is performed by plasma-enhanced chemical vapor deposition (PECVD).

25. The method of claim 21, wherein the step c) of depositing a thin silicon-rich oxide layer includes controlling the composition of the silicon-rich oxide layer to have an elemental molar ratio of silicon to oxygen between about 0.51 and about one.

26. The method of claim 21, further comprising the step of:
e) providing a substrate.

27. The method of claim 21, further comprising the step of:
f) patterning the conductive anode layer.

28. The method of claim 21, further comprising the step of:
g) patterning the conductive cathode layer.

29. A two-terminal electronic isolation device made by the method of claim 21.

30. An integrated circuit comprising the two-terminal electronic isolation device of claim 29.

31. A method for fabricating a two-terminal electronic isolation device, the method comprising the steps of:
a) providing a substrate comprising an insulating layer over a planar silicon wafer,
b) forming a conductive anode layer on the substrate,
c) forming a thin tunnel-junction layer contiguous with the anode layer,
d) depositing a thin silicon-rich oxide layer having a composition of SiOx, wherein x is less than two, contiguous with the tunnel-junction layer, and
e) forming a conductive cathode layer contiguous with the silicon-rich oxide layer.

32. The method of claim 31, wherein the conductive-anode layer-forming step b) comprises depositing titanium.

33. The method of claim 31, wherein the conductive-anode layer-forming step b) comprises depositing titanium nitride.

34. The method of claim 31, wherein the conductive-cathode layer-forming step e) comprises depositing titanium.

35. The method of claim 31, wherein the conductive-cathode layer-forming step e) comprises depositing titanium nitride.

36. The method of claim 31, wherein the step d) of depositing a thin silicon-rich oxide layer is performed by rapid thermal chemical vapor deposition (RTCVD).

37. The method of claim 31, wherein the step d) of depositing a thin silicon-rich oxide layer is performed by plasma-enhanced chemical vapor deposition (PECVD).

38. The method of claim 31, wherein the step d) of depositing a thin silicon-rich oxide layer includes controlling the composition of the silicon-rich oxide layer to have an elemental molar ratio of silicon to oxygen between about 0.51 and about one.

39. A two-terminal electronic isolation device made by the method of claim 31.

40. An integrated circuit comprising the two-terminal electronic isolation device of claim 39.
